(19) United States
(12) Patent Application Publication
(10) Pub. No.: US 2023/0011973 A1
(43) Pub. Date: Jan. 12, 2023

(54) MEMORY DEVICE USING SEMICONDUCTOR ELEMENT

(71) Applicant: Unisantis Electronics Singapore Pte. Ltd., Singapore (SG)

(72) Inventors: Nozomu HARADA, Tokyo (JP); Koji SAKUI, Tokyo (JP)

(21) Appl. No.: 17/858,574

(22) Filed: Jul. 6, 2022

(30) Foreign Application Priority Data
Jul. 9, 2021 (JP) PCT/JP2021/025909

(51) Int. Cl. H01L 27/108; G11C 5/06

(52) U.S. Cl. CPC H01L 27/10802; G11C 5/063

(57) ABSTRACT

A P layer 2 having a band shape is on an insulating substrate 1. An N⁺ layer 3a connected to a first source line SL1 and an N⁺ layer 3b connected to a first bit line are on respective sides of the P layer 2 in a first direction parallel to the insulating substrate. A first gate insulating layer 4a surrounds a portion of the P layer 2 connected to the N⁺ layer 3a, and a second gate insulating layer 4b surrounds the P layer 2 connected to the N⁺ layer 3b. A first gate conductor layer 5a connected to a first plate line and a second gate conductor layer 5b connected to a second plate line are isolated from each other and cover two respective side surfaces of the first gate insulating layer 4a in a second direction perpendicular to the first direction. A third gate conductor layer 5c connected to a first word line surrounds the second gate insulating layer 4b. These components constitute a dynamic flash memory.

### TECHNICAL FIELD

The present invention relates to a memory device using a semiconductor element.

### BACKGROUND ART

In recent years, a higher degree of integration and a higher performance of memory elements have been desired in the development of LSI (Large Scale Integration) technology.

Capacitorless memory elements include a PCM (Phase Change Memory, see, for example, NPL 1) to which a variable resistance element is connected, an RRAM (Resistive Random Access Memory, see, for example, NPL 2), and an MRAM (Magneto-resistive Random Access Memory, see, for example, NPL 3) in which the direction of a magnetic spin is changed by a current to change the resistance. Since these memory elements do not require a capacitor, the degree of integration of the memory elements can be increased. There is also a capacitorless DRAM memory cell constituted by a single MOS transistor (see NPL 4). The present application relates to a dynamic flash memory that includes neither a variable resistance element nor a capacitor and can be constituted only by MOS transistors.

FIG. 8 illustrates a write operation of the aforementioned capacitorless DRAM memory cell constituted by a single MOS transistor, FIG. 9 illustrates an issue in the operation of the capacitorless DRAM memory cell, and FIG. 10 illustrates a read operation of the capacitorless DRAM memory cell (see NPLs 7 to 10).

FIG. 8 illustrates the write operation of the DRAM memory cell. FIG. 8(a) illustrates a “1” write state. The memory cell is constituted by a source N⁺ layer 103 (hereinafter, a semiconductor region that contains a donor impurity at a high concentration is referred to as an “N⁺ layer”) which is formed in an SOI substrate 100 and to which a source line SL is connected, a drain N⁺ layer 104 which is formed in the SOI substrate 100 and to which a bit line BL is connected, a gate conductor layer 105 to which a word line WL is connected, and a floating body 102 of a MOS transistor 110a. In this manner, the DRAM memory cell is constituted by the single MOS transistor 110a without any capacitor. A SiO₂ layer 101 of the SOI substrate is in contact with the floating body 102, which is a P layer (hereinafter, a semiconductor region containing an acceptor impurity is referred to as a “P layer”), right under the floating body 102. When “1” is written in this memory cell constituted by the single MOS transistor 110a, the MOS transistor 110a is operated in a saturated region. Specifically, a channel 107 for electrons extending from the source N⁺ layer 103 has a pinch-off point 108 and does not reach the drain N⁺ layer 104 to which the bit line is connected. When a high voltage is applied to both the bit line BL connected to the drain N⁺ layer 104 and the word line WL connected to the gate conductor layer 105 and the MOS transistor 110a is operated at a gate voltage that is about ½ of the drain voltage, the electric field intensity is maximized at the pinch-off point 108 near the drain N⁺ layer 104. As a result, accelerated electrons flowing from the source N⁺ layer 103 toward the drain N⁺ layer 104 collide with the Si lattice, and electron-hole pairs are generated by kinetic energy lost at the time of collision (impact ionization phenomenon). Most of the generated electrons (not illustrated) reach the drain N⁺ layer 104. Only a small number of very hot electrons jump over a gate oxide film 109 to reach the gate conductor layer 105. The floating body 102 is charged with holes 106 simultaneously generated. In this case, since the floating body 102 is of P-type Si, the generated holes contribute to an increment of the majority carrier. The floating body 102 is filled with the generated holes 106. When the voltage of the floating body 102 becomes higher than that of the source N⁺ layer 103 by Vb or more, the further generated holes are discharged to the source N⁺ layer 103. Vb is a built-in voltage of a PN junction between the source N⁺ layer 103 and the P-layer floating body 102, and is equal to about 0.7 V. FIG. 8(b) illustrates the floating body 102 charged to be saturated with the generated holes 106.

A “0” write operation of a memory cell 110 will be described next with reference to FIG. 8(c). The memory cell 110a in which “1” is written and a memory cell 110b in which “0” is written are present at random for the common selection word line WL. FIG. 8(c) illustrates rewriting from the “1” write state to a “0” write state. When “0” is written, the voltage of the bit line BL is set to a negative bias, so that the PN junction between the drain N⁺ layer 104 and the P-layer floating body 102 is forward biased. As a result, the holes 106 generated in the floating body 102 in the previous cycle flow into the drain N⁺ layer 104 connected to the bit line BL. When the write operation ends, two memory cell states, i.e., the memory cell 110a filled with the generated holes 106 (FIG. 8(b)) and the memory cell 110b from which the generated holes are discharged (FIG. 8(c)), are obtained. The potential of the floating body 102 of the memory cell 110a filled with the holes 106 is higher than the potential of the floating body 102 without any generated holes. Thus, a threshold voltage of the memory cell 110a is lower than a threshold voltage of the memory cell 110b. FIG. 8(d) illustrates this state.

An issue in the operation of this memory cell constituted by a single MOS transistor will be described next with reference to FIG. 9. As illustrated in FIG. 9(a), a capacitance C_{FB} of the floating body 102 is equal to the sum of a capacitance C_{WL} between the gate to which the word line is connected and the floating body 102, a junction capacitance C_{SL} of the PN junction between the source N⁺ layer 103 to which the source line is connected and the floating body 102, and a junction capacitance C_{BL} of the PN junction between the drain N⁺ layer 103 to which the bit line is connected and the floating body 102, and is denoted by

$${\text{C}}_{\text{FB}} {\text{=C}}_{\text{WL}} {\text{+C}}_{\text{BL}} {\text{+C}}_{\begin{matrix}\text{SL} \\ \end{matrix}}$$

Thus, if a word line voltage V_{WL} fluctuates at the time of writing, the voltage of the floating body 102 that serves as a storage node (contact point) of the memory cell is also affected by the fluctuation. FIG. 9(b) illustrates this state. If the word line voltage V_{WL} rises from 0 V to V_{ProgWL} at the time of writing, the voltage V_{FB} of the floating body 102 also rises from V_{FB1}, which is a voltage in the initial state before the word line voltage changes, to V_{FB2} due to capacitive coupling with the word line. An amount of the voltage change ΔV_{FB} is denoted by

$$\begin{matrix}Δ {\text{V}}_{\text{FB}} {\text{=V}}_{\text{FB2}} {\text{-V}}_{\text{FB1}} \\ {\text{C}}_{\text{WL}} \text{/} {\text{(C}}_{\text{WL}} {\text{+C}}_{\text{BL}} {\text{+C}}_{\text{SL}} \text{)} \text{×} {\text{V}}_{\text{ProgWL}}\end{matrix}$$

Here, β is denoted by

$$β \text{=} {\text{C}}_{\text{WL}} {\text{/(C}}_{\text{WL}} {\text{+C}}_{\text{BL}} {\text{+C}}_{\text{SL}} \text{)}$$

and is referred to as a coupling ratio. In such a memory cell, the contribution ratio of C_{WL} is large. For example, C_{WL}:C_{BL}:C_{SL} = 8:1:1 holds. In this case, β = 0.8. For example, if the voltage of the word line changes from 5 V which is the voltage at the time of writing to 0 V after the end of writing, the floating body 102 is subjected to fluctuation noise of as large as 5 V × β = 4 V due to the capacitive coupling between the word line and the floating body 102. Thus, there is an issue in that a sufficient margin of the potential difference between the “1” potential and the “0” potential of the floating body is not provided at the time of writing.

FIG. 10 illustrates the read operation. FIG. 10(a) illustrates the “1” write state. FIG. 10(b) illustrates the “0” write state. However, even if Vb is written in the floating body 102 in writing of “1”, when the voltage of the word line returns to 0 V upon the completion of the writing, the voltage of the floating body 102 actually lowers to a negative bias. When “0” is written, the voltage of the floating body 102 further lowers to a negative bias. Thus, the margin of the potential difference between “1” and “0” cannot be sufficiently large at the time of writing as indicated in FIG. 10(c). This small operation margin is a big issue for this DRAM memory cell. In addition, the degree of integration of the DRAM memory cells is desirably increased.

### CITATION LIST

### Non Patent Literature

[NPL 1] H. S. Philip Wong, S. Raoux, S. Kim, Jiale Liang, J. R. Reifenberg, B. Rajendran, M. Asheghi, and K. E. Goodson: “Phase Change Memory”, Proceeding of IEEE, Vol. 98, No. 12, December, pp. 2201-2227 (2010)

[NPL 2] T. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and High Speed Switching of Ti-doped NiO ReRAM under the Unipolar Voltage Source of less than 3 V”, IEDM (2007)

[NPL 3] W. Kang, L. Zhang, J. Klein, Y. Zhang, D. Ravelosona, and W. Zhao: “Reconfigurable Codesign of STT-MRAM Under Process Variations in Deeply Scaled Technology”, IEEE Transaction on Electron Devices, pp. 1-9 (2015)

[NPL 4] M. G. Ertosum, K. Lim, C. Park, J. Oh, P. Kirsch, and K. C. Saraswat: “Novel Capacitorless Single-Transistor Charge-Trap DRAM (1T CT DRAM) Utilizing Electron”, IEEE Electron Device Letter, Vol. 31, No. 5, pp. 405-407 (2010)

[NPL 5] E. Yoshida and T. Tanaka: “A Capacitorless 1T-DRAM Technology Using Gate-Induced Drain-Leakage (GIDL) Current for Low-Power and High-Speed Embedded Memory”, IEEE Transactions on Electron Devices, Vol. 53, No. 4, pp. 692-697, Apr. 2006.

### SUMMARY OF INVENTION

### Technical Problem

In a capacitorless single-transistor DRAM (gain cell) that is a memory device using a MOS transistor, the capacitive coupling between a word line and a floating body is large. Thus, there is an issue that when the potential of the word line is fluctuated at the time of data reading or data writing, the fluctuation of the potential is directly transmitted as noise to the MOS transistor body. This consequently causes an issue of erroneous reading and erroneous rewriting of stored data and makes it difficult to put the capacitorless single-transistor DRAM (gain cell) into practical use. Thus, the issues described above are to be addressed and the performance and the density of memory cells are to be increased.

### Solution to Problem

To address the issues described above, according to the present invention, a memory device using a semiconductor element includes
a first semiconductor layer standing on a substrate in a direction perpendicular to the substrate, having a band shape, and serving as a floating body,
a first impurity layer and a second impurity layer connected to respective ends of the first semiconductor layer in a first direction parallel to the substrate,
a first gate insulating layer covering both side surfaces, of a portion of the first semiconductor layer adjacent to the first impurity layer, in a second direction parallel to the substrate and perpendicular to the first direction,
a first gate conductor layer and a second gate conductor layer covering respective side surfaces of the first gate insulating layer and isolated from each other in plan view,
a second gate insulating layer covering a portion of the first semiconductor layer adjacent to the second impurity layer, and
a third gate conductor layer covering the second gate insulating layer, wherein
the first gate conductor layer, the second gate conductor layer, the third gate conductor layer, the first impurity layer, and the second impurity layer are configured to
perform a data write operation, a data read operation, and a data erase operation in accordance with control of voltages applied to the first gate conductor layer, the second gate conductor layer, the third gate conductor layer, the first impurity layer, and the second impurity layer (a first invention).

According to a second invention, in the first invention described above,
the first impurity layer is connected to a first source line,
the first gate conductor layer is connected to a first plate line,
the second gate conductor layer is connected to a second plate line,
the third gate conductor layer is connected to a first word line,
the second impurity layer is connected to a first bit line, and
in plan view, the first plate line, the second plate line, and the first word line extend in an identical direction that is the second direction and the first bit line extends in the first direction (the second invention).

According to a third invention, in the first invention described above, in the direction perpendicular to the substrate, a height of a portion of the first semiconductor layer covered with the third gate conductor layer is lower than a height of a portion of the first semiconductor layer sandwiched by the first gate conductor layer and the second gate conductor layer (the third invention).

According to a fourth invention, in the first invention described above, in the direction perpendicular to the substrate, the first semiconductor layer includes, in a lower portion of the first semiconductor layer, a semiconductor layer having an impurity concentration higher than an impurity concentration in an upper portion of the first semiconductor layer (the fourth invention).

According to a fifth invention, in the first invention described above, in plan view, the third gate conductor layer includes two divisional conductor layers covering the second gate insulating layer on respective sides of the first semiconductor layer (the fifth invention).

According to a sixth invention, in the first invention described above,

the substrate is an insulating substrate (the sixth invention).

According to a seventh invention, in the second invention described above, the memory device using a semiconductor element includes
a second semiconductor layer parallel to the first semiconductor layer on the substrate and having a band shape in plan view,
a third impurity layer and a fourth impurity layer connected to respective ends of the second semiconductor layer in the first direction,
the first gate insulating layer covering both side surfaces, of a portion of the second semiconductor layer adjacent to the third impurity layer, in the second direction,
the second gate conductor layer extending to the second semiconductor layer and covering one side surface of the first gate insulating layer covering the second semiconductor layer in plan view,
a fourth gate conductor layer covering a side surface, of the first gate insulating layer, opposite the second gate conductor layer in plan view,
a fourth gate insulating layer covering a portion of the second semiconductor layer adjacent to the fourth impurity layer,
the third gate conductor layer extending to cover the fourth gate insulating layer,
a first wiring conductor layer extending in the second direction and connecting the first gate conductor layer and the fourth gate conductor layer to each other via first contact holes located above the first gate conductor layer and the fourth gate conductor layer,
a second wiring conductor layer extending in the second direction and connected to the second gate conductor layer via a second contact hole located above the second gate conductor layer,
a third wiring conductor layer extending in the second direction and connected to the first impurity layer and the third impurity layer via third contact holes located above the first impurity layer and the third impurity layer,
a fourth wiring conductor layer extending in the first direction and connected to the second impurity layer via a fourth contact hole located above the second impurity layer, and
a fifth wiring conductor layer extending in the first direction and connected to the fourth impurity layer via a fifth contact hole located above the fourth impurity layer (the seventh invention).

According to an eighth invention, in the sixth invention described above, the memory device using a semiconductor element includes a sixth wiring conductor layer extending in the second direction and connected to the third gate conductor layer via a sixth contact hole located above the third gate conductor layer (the eighth invention).

According to a ninth invention, in the first invention described above, a first gate capacitance between the first gate conductor layer and the first semiconductor layer, a second gate capacitance between the second gate conductor layer and the first semiconductor layer, or a total gate capacitance of the first gate capacitance and the second gate capacitance is larger than a third gate capacitance between the third gate conductor layer and the first semiconductor layer (the ninth invention).

According to a tenth invention, in the first invention described above, the first gate conductor layer, the second gate conductor layer, the third gate conductor layer, the first impurity layer, and the second impurity layer are configured to perform the data write operation of holding a group of holes or a group of electrons that is a majority carrier in the first semiconductor layer and is generated by an impact ionization phenomenon or a gate-induced drain leakage current in the first semiconductor layer, in accordance with control of voltages applied to the first gate conductor layer, the second gate conductor layer, the third gate conductor layer, the first impurity layer, and the second impurity layer, and

the data erase operation of discharging the group of holes or the group of electrons that is the majority carrier in the first semiconductor layer from the first semiconductor layer, in accordance with control of voltages applied to the first gate conductor layer, the second gate conductor layer, the third gate conductor layer, the first impurity layer, and the second impurity layer (the tenth invention).

### [BRIEF DESCRIPTION OF DRAWINGS

FIG. 1 is a structural diagram of a memory device according to a first embodiment.

FIG. 2 is a diagram for describing a mechanism of an erase operation of the memory device according to the first embodiment.

FIG. 3 is a diagram for describing a mechanism of a write operation of the memory cell according to the first embodiment.

FIG. 4 is a diagram for describing a mechanism of a read operation of the memory device according to the first embodiment.

FIG. 5A is a structural diagram of a memory device according to a second embodiment.

FIG. 5B is a structural diagram of the memory device according to the second embodiment.

FIG. 6 is a structural diagram of a memory device according to a third embodiment.

FIG. 7 is a structural diagram of a memory device according to a fourth embodiment.

FIG. 8 is a diagram for describing an issue in an operation of a capacitorless DRAM memory cell of the related art.

FIG. 9 is a diagram for describing an issue in the operation of the capacitorless DRAM memory cell of the related art.

FIG. 10 is a diagram illustrating a read operation of the capacitorless DRAM memory cell of the related art.

### DESCRIPTION OF EMBODIMENTS

A structure, a driving method, and a production method of a memory device (hereinafter, referred to as a dynamic flash memory), using a semiconductor element, according to the present invention will be described below with reference to the drawings.

### First Embodiment

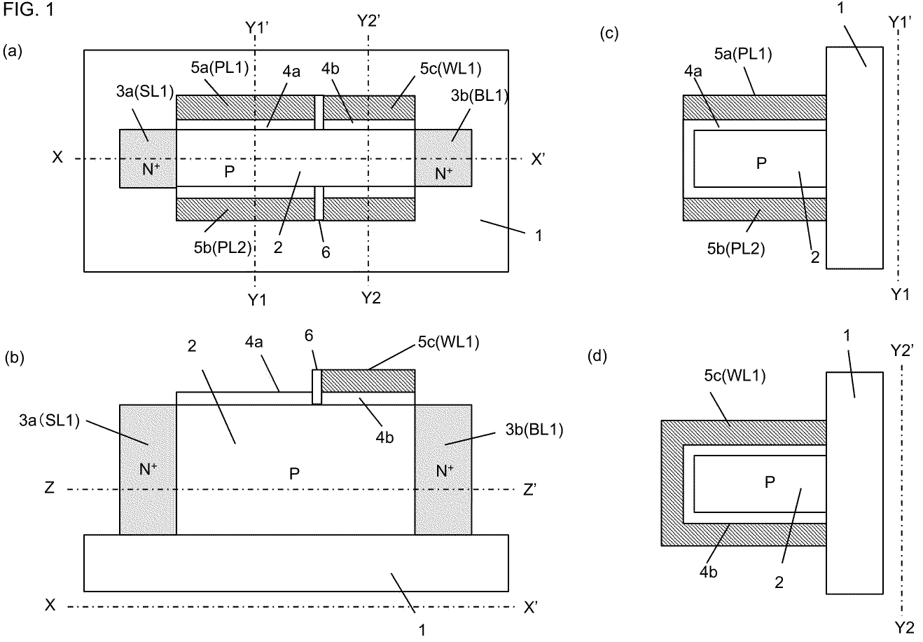

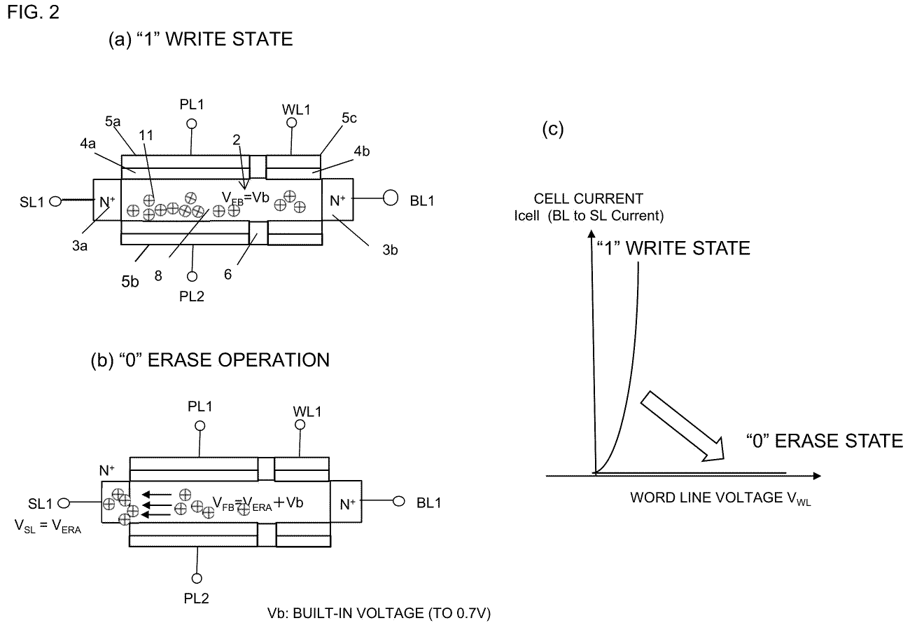

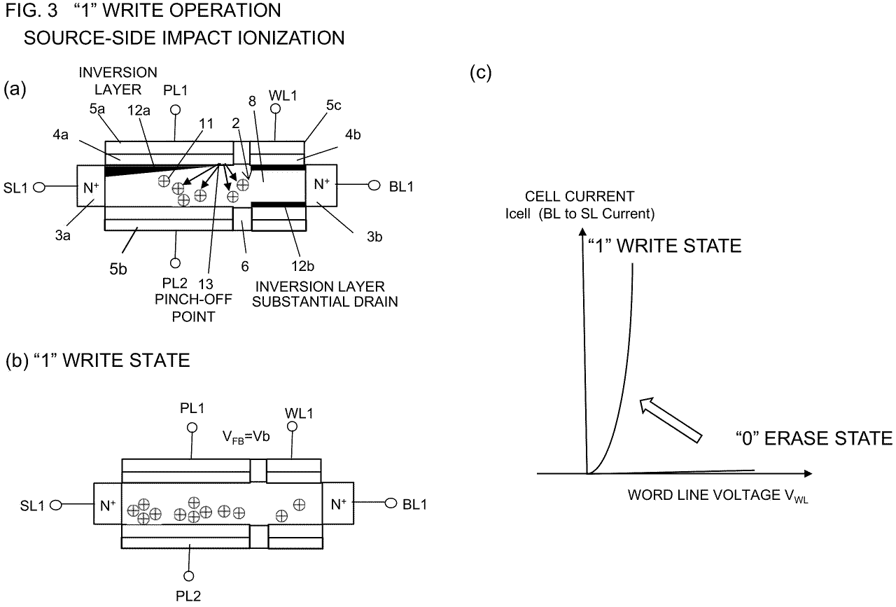

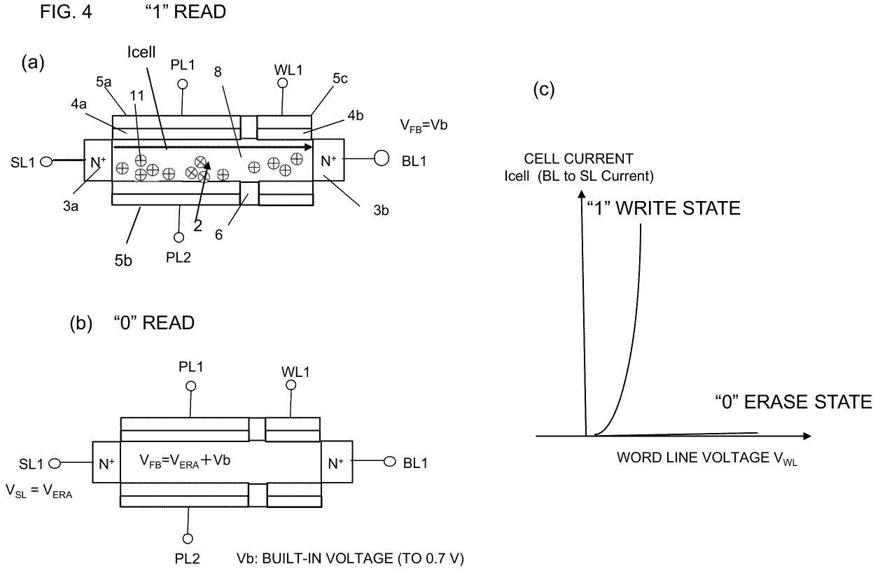

A structure, an operation mechanism, and a production method of a first dynamic flash memory cell according to a first embodiment of the present invention will be described with reference to FIGS. 1 to 4. The structure of the first dynamic flash memory cell will be described with reference to FIG. 1. A data erase mechanism will be described with reference to FIG. 2. A data write mechanism will be described with reference to FIG. 3. A data read mechanism will be described with reference to FIG. 4.

FIG. 1 illustrates a structure of the first dynamic flash memory cell according to the first embodiment of the present invention. FIG. 1(a) is a horizontal sectional view taken along line Z-Z’ in FIG. 1(b). FIG. 1(b) is a vertical sectional view taken along line X-X’ in FIG. 1(b). FIG. 1(c) is a vertical sectional view taken along line Y1-Y1’ in FIG. 1(a). FIG. 1(d) is a vertical sectional view taken along line Y2-Y2’ in FIG. 1(a).

A P layer 2 (an example of a “first semiconductor layer” in the claims) having a band shape is on an insulating substrate 1 (an example of an “insulating substrate” in the claims). An N⁺ layer 3a (an example of a “first impurity layer” in the claims) and an N⁺ layer 3b (an example of a “second impurity layer” in the claims) are on respective sides of the P layer 2 in an X-X’ direction. A portion of the P layer 2 connected to the N⁺ layer 3a is surrounded by a first gate insulating layer 4a (an example of a “first gate insulating layer” in the claims), and the P layer 2 connected to the N⁺ layer 3b is surrounded by a second gate insulating layer 4b (an example of a “second gate insulating layer” in the claims). Two side surfaces of the first gate insulating layer 4a in a Y1-Y1’ direction are respectively covered with a first gate conductor layer 5a (an example of a “first gate conductor layer” in the claims) and a second gate conductor layer 5b (an example of a “second gate conductor layer”) that are isolated from each other. The second gate insulating layer 4b is surrounded by a third gate conductor layer 5c (an example of a “third gate conductor layer” in the claims). The first gate conductor layer 5a and the second gate conductor layer 5b are isolated from the third gate conductor layer 5c by an insulating layer 6. In this manner, a dynamic flash memory cell including the N⁺ layers 3a and 3b, the P layer 2, the first gate insulating layer 4a, the second gate insulating layer 4b, the first gate conductor layer 5a, the second gate conductor layer 5b, and the third gate conductor layer 5c is formed.

As illustrated in FIG. 1, the N⁺ layer 3a is connected to a first source line SL1 (an example of a “first source line” in the claims). The N⁺ layer 3b is connected to a first bit line BL1 (an example of a “first bit line” in the claims). The first gate conductor layer 5a is connected to a first plate line PL1 (an example of a “first plate line” in the claims). The second gate conductor layer 5b is connected to a second plate line PL2 (an example of a “second plate line” in the claims). The third gate conductor layer 5c is connected to a first word line WL1 (an example of a “first word line” in the claims).

A mechanism of a data erase operation will be described with reference to FIG. 2. FIG. 2(a) illustrates a state in which a group of holes 11 generated by impact ionization in the previous cycle is accumulated in a channel region 8 of the P layer 2 prior to the data erase operation. The channel region 8 between the N⁺ layers 3a and 3b is electrically isolated from the substrate 1 and thus is a floating body. A voltage lower than that of the first plate line PL1 is applied to the second plate line PL2. Thus, the group of holes 11 is accumulated mainly in a portion of the P layer 2 adjacent to the second gate conductor layer 5b connected to the second plate line PL2. Part of the group of holes 11 is also accumulated in a portion of the channel region 8 surrounded by the third gate conductor layer 5c. And. As illustrated in FIG. 2(b), during the data erase operation, a voltage of the first source line SL1 is set to a negative voltage V_{ERA}. For example, V_{ERA} is equal to -3 V. As a result, regardless of the value of the initial potential of the channel region 8, a PN junction between the channel region 8 and the N⁺ layer 3a serving as a source connected to the first source line SL1 is forward biased. As a result, the group of holes 11 generated by impact ionization in the previous cycle and accumulated in the channel region 8 is drawn into the N⁺ layer 3a serving as the source, and a potential V_{FB} of the channel region 8 becomes V_{FB} = V_{ERA} + Vb. Here, Vb denotes a built-in voltage of the PN junction and is approximately equal to 0.7 V. Thus, in the case of V_{ERA} = -3 V, the potential of the channel region 8 is equal to -2.3 V. This value corresponds to a potential state of the channel region 8 in an erase state. Thus, when the potential of the channel region 8 that is the floating body becomes a negative voltage, a threshold voltage of an N-channel MOS transistor of the first dynamic flash memory cell increases because of a substrate bias effect. As a result, as illustrated in FIG. 2(c), a threshold voltage of the third gate conductor layer 5c to which the first word line WL1 is connected increases. This erase state of the channel region 8 corresponds to logical storage data “0”. The above-described conditions of the voltages applied to the first bit line BL1, the first source line SL1, the first word line WL1, the first plate line PL1, and the second plate line PL2 and the potential of the floating body are an example for performing the data erase operation, and may be other operation conditions under which the data erase operation can be performed.

FIG. 3 illustrates a data write operation of the first dynamic flash memory cell. As illustrated in FIG. 3(a), for example, 0 V is input to the N⁺ layer 3a to which the first source line SL1 is connected. For example, 3 V is input to the N⁺ layer 3b to which the first bit line BL1 is connected. For example, 2 V is input to the first gate conductor layer 5a to which the first plate line PL1 is connected. For example, 0 V is input to the second gate conductor layer 5b to which the second plate line PL2 is connected. For example, 5 V is input to the third gate conductor layer 5c to which the first word line WL1 is connected. As a result, as illustrated in FIG. 3(a), an inversion layer 12a is formed in the channel region 8 on the inner side of the first gate conductor layer 5a to which the first plate line PL1 is connected, and a first N-channel MOS transistor region including the first gate conductor layer 5a is operated in a saturated region. As a result, the inversion layer 12a on the inner side of the first gate conductor layer 5a connected to the first plate line PL1 has a pinch-off point 13. On the other hand, a second N-channel MOS transistor region including the third gate conductor layer 5c connected to the first word line WL1 is operated in the linear region. As a result, an inversion layer 12b not having the pinch-off point is formed on the entire surface in the channel region 8 on the inner side of the third gate conductor layer 5c connected to the first word line WL1. The inversion layer 12b on the entire surface on the inner side of the third gate conductor layer 5c connected to the first word line WL1 functions as a substantial drain of the first N-channel MOS transistor region the first N-channel MOS transistor region region. As a result, the electric field becomes maximum in a first boundary region of the channel region 8 between the first N-channel MOS transistor region and the second N-channel MOS transistor region, and an impact ionization phenomenon occurs in this region. As a result of this impact ionization phenomenon, electrons flow from the N⁺ layer 3a to which the first source line SL1 is connected toward the N⁺ layer 3b to which the first bit line BL1 is connected in the second N-channel MOS transistor region. The accelerated electrons collide with lattice Si atoms, and electron-hole pairs are generated by the kinetic energy of the collision. Some of the generated electrons flow to the first gate conductor layer 5a and the third gate conductor layer 5c, whereas most of the generated electrons flow to the N⁺ layer 3b to which the first bit line BL1 is connected. In writing of “1”, a gate-induced drain leakage (GIDL) current may be used to generate electron-hole pairs, and the floating body FB may be filled with the generated group of holes (see, for example, NPL 5).

As illustrated in FIG. 3(b), the generated group of holes 11, which is a majority carrier in the channel region 8, charges the channel region 8 to a positive bias. Since the N⁺ layer 3a connected to the first source line SL1 has 0 V, the channel region 8 is charged to the built-in voltage Vb (about 0.7 V) of the PN junction between the channel region 8 and the N⁺ layer 3a connected to the first source line SL1. When the channel region 8 is charged to a positive bias, the threshold voltages of the first N-channel MOS transistor region and the second N-channel MOS transistor region decrease because of the substrate bias effect. Consequently, as illustrated in FIG. 3(c), the threshold voltage of the second N-channel MOS transistor region to which the first word line WL1 is connected decreases. This write state of the channel region 8 is assigned to logical storage data “1”. The generated group of holes 11 is accumulated mainly in a portion of the P layer 2 adjacent to the second gate conductor layer 5b. Thus, the stable substrate bias effect can be obtained.

During the data write operation, electron-hole pairs may be generated by an impact ionization phenomenon or a GIDL current in a second boundary region between the N⁺ layer 3a and the channel region 8 or a third boundary region between the N⁺ layer 3b and the channel region 8 instead of the first boundary region described above, and the channel region 8 may be charged with the generated group of holes 11. The above-described conditions of the voltages applied to the first bit line BL1, the first source line SL1, the first word line WL1, the first plate line PL1, and the second plate line PL2 are an example for performing the data write operation, and may be other operation conditions under which the data write operation can be performed.

A data read operation of the first dynamic flash memory cell will be described with reference to FIG. 4(a) to FIG. 4(c). As illustrated in FIG. 4(a), when the channel region 8 is charged to the built-in voltage Vb (about 0.7 V), the threshold voltage of the N-channel MOS transistor decreases because of the substrate bias effect. This state is assigned to logical storage data “1”. As illustrated in FIG. 4(b), when a memory block to be selected prior to writing is in the erase state “0” in advance, the floating voltage V_{FB} of the channel region 8 is equal to V_{ERA} + Vb. The write state “1” is stored at random through the data write operation. As a result, logical storage data of logical “0” and logical “1” is created. As illustrated in FIG. 4(c), reading is performed by a sense amplifier using a level difference between the two threshold voltages for this first word line WL1. During this read operation, by making a first gate capacitance between the first gate conductor layer 5a and the P layer 2, a second gate capacitance between the second gate conductor layer 5b and the P layer 2, or a total capacitance of the first gate capacitance and the second gate capacitance larger than a third gate capacitance between the third gate conductor layer 5c and the P layer 2, the fluctuation of the floating voltage of the channel region 8 at the time of driving can be greatly suppressed. Consequently, a read operation of the first dynamic flash memory cell is performed with a wide operation margin. In data reading, the voltage applied to the first gate conductor layer 5a connected to the first plate line PL1 is set to be higher than the threshold voltage at the time of logical storage data “1” and to be lower than the threshold voltage at the time of logical storage data “0”. Consequently, a characteristic that no current flows even if the voltage of the word line WL is increased in reading of the logical storage data “0” is obtained as illustrated in FIG. 4(c). The above-described conditions of the voltages applied to the first bit line BL1, the first source line SL1, the first word line WL1, the first plate line PL1, and the second plate line PL2 and the potential of the floating body are an example for performing the data read operation, and may be other operation conditions under which the data read operation can be performed. This read operation may be performed using a bipolar operation.

The operations of the dynamic flash memory may also be performed in a structure in which the polarities of the conductivity types of the N⁺ layers 3a and 3b and the P layer 2 illustrated in FIG. 1 are reversed. In this case, electrons serve as the majority carrier in the P layer 2. Thus, a group of electrons generated by impact ionization is accumulated in the channel region 8, and the “1” state is set.

In FIG. 1, the first gate conductor layer 5a and the second gate conductor layer 5b are electrically isolated from the third gate conductor layer 5c by the insulating layer 6. Alternatively, the second gate insulating layer 4b may be extended to cover the exposed P layer 2 and the first gate conductor layer 5a, so that the first gate conductor layer 5a and the second gate conductor layer 5b are insulated and isolated from the third gate conductor layer 5c. Likewise, the first gate insulating layer 4a may be extended to cover the exposed P layer 2 and the third gate conductor layer 5c, so that the first gate conductor layer 5a and the second gate conductor layer 5b are insulated and isolated from the third gate conductor layer 5c. This insulation/isolation may be performed using any of the other methods.

In FIG. 1, the first gate insulating layer 4a covers both side surfaces and an upper surface of the P layer 2. Alternatively, the first gate insulating layer 4a may cover at least both side surfaces of the P layer 2.

In FIG. 1, a P layer having a lower acceptor impurity concentration than the P layer 2 may be disposed between the N⁺ layer 3a and the P layer 2, between the N⁺ layer 3b and the P layer 2, or between the N⁺ layer 3a and the P layer 2 and between the N⁺ layer 3b and the P layer 2. An N layer having a lower donor impurity concentration than the N⁺ layers 3a and 3b may be disposed between the N⁺ layer 3a and the P layer 2, between the N⁺ layer 3b and the P layer 2, or between the N⁺ layer 3a and the P layer 2 and between the N⁺ layer 3b and the P layer 2.

An SOI substrate may be used as the insulating substrate 1 illustrated in FIG. 1. Alternatively, a semiconductor substrate may be used. After the formation of the P layer 2, the upper surface of the semiconductor substrate at a bottom portion of the P layer 2 and an outer periphery portion of the P layer 2 may be oxidized to form the insulating substrate 1.

In FIG. 1, the N⁺ layer 3a is connected to the first source line SL1, and the N⁺ layer 3b is connected to the first bit line BL1. Alternatively, the N⁺ layer 3a may be connected to the first bit line BL1, and the N⁺ layer 3b may be connected to the first source line SL1. The operations of the dynamic flash memory can also be performed with this configuration.

The present embodiment provides features below.

### Feature 1

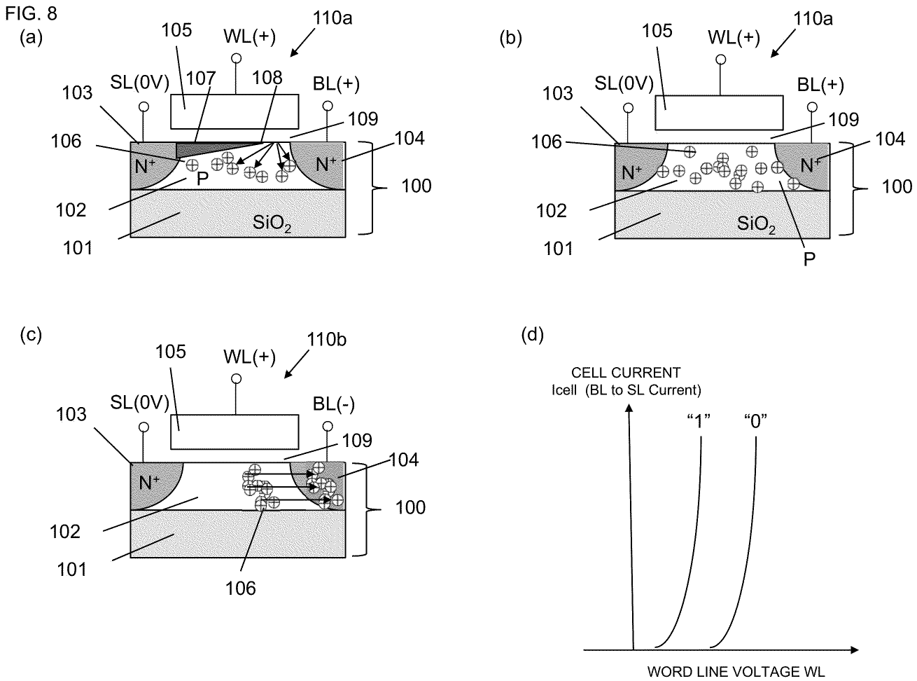

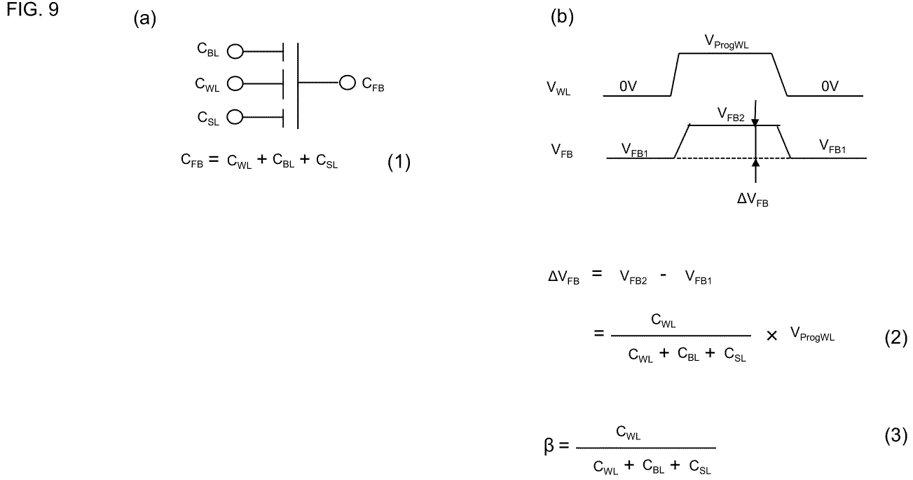

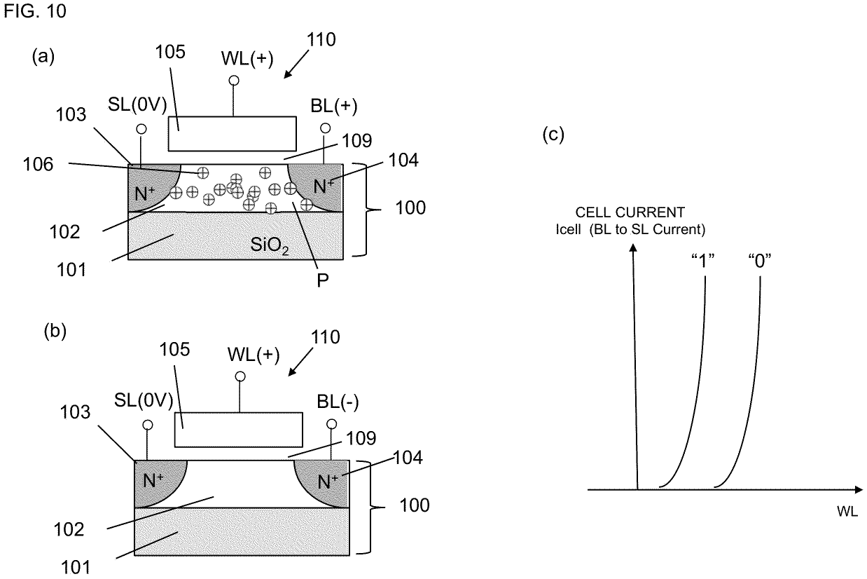

In the related art illustrated in FIGS. 8 to 10, “1” is written by accumulating the group of holes 106 in the P-layer floating body 102. The floating body 102 greatly fluctuates depending on a read pulse voltage applied to the word line. This voltage fluctuation causes an issue of leakage of the accumulated group of holes 106 from the floating body 102. Thus, there is an issue that a sufficient margin of the potential difference between the “1” potential and the “0” potential of the floating body is not provided at the time of writing. By contrast, as described in the present embodiment, in addition to the third gate conductor layer 5c connected to the first word line WL1, the first gate conductor layer 5a and the second gate conductor layer 5b for controlling the voltage of the floating body of the P layer 2 serving as the channel region are provided. Thus, the fluctuation of the floating body voltage of the P layer 2 that occurs when a drive pulse voltage is applied to the first word line can be suppressed. As a result, the margin of the potential difference between the “1” potential and the “0” potential of the floating body is increased at the time of writing.

### Feature 2

As illustrated in FIG. 1, the first gate conductor layer 5a connected to the first plate line and the second gate conductor layer 5b connected to the second plate line are disposed on the respective side surfaces of the P layer 2. A second plate line voltage is set to be lower than a first plate line voltage, so that the generated group of holes 11 can be accumulated in a portion of the P layer 2 adjacent to the second gate conductor layer 5b during writing of “1” described in FIG. 3. During reading of “1”, the second plate line voltage is set to be lower than a read on voltage of the first plate line, so that the group of holes can be stably held in the portion of the P layer 2 adjacent to the second gate conductor layer 5b during the read operation as illustrated in FIG. 4. Thus, a large margin of the potential difference is stably obtained.

### Second Embodiment

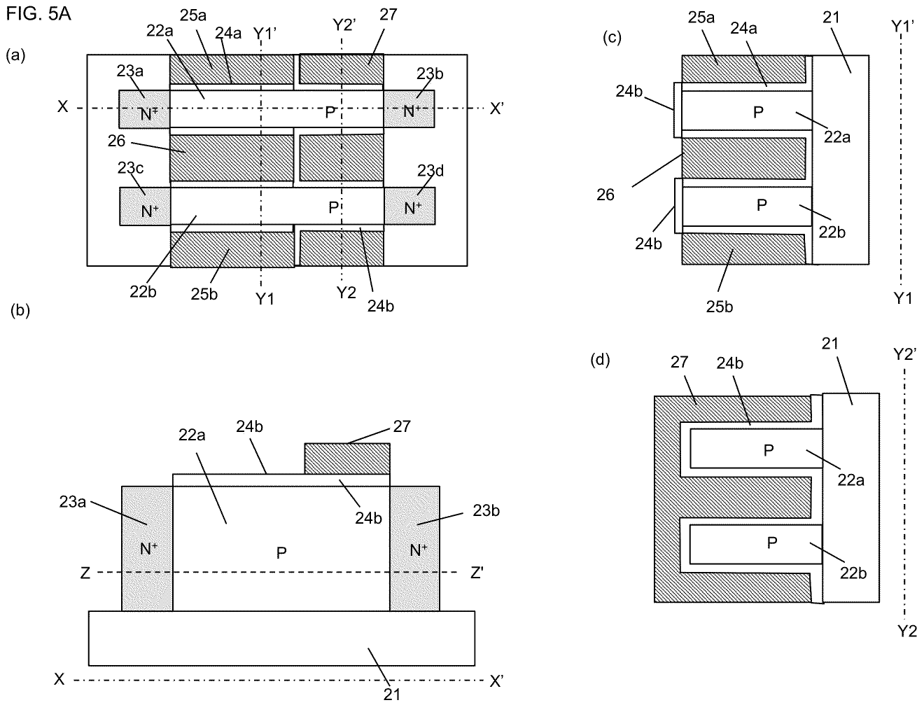

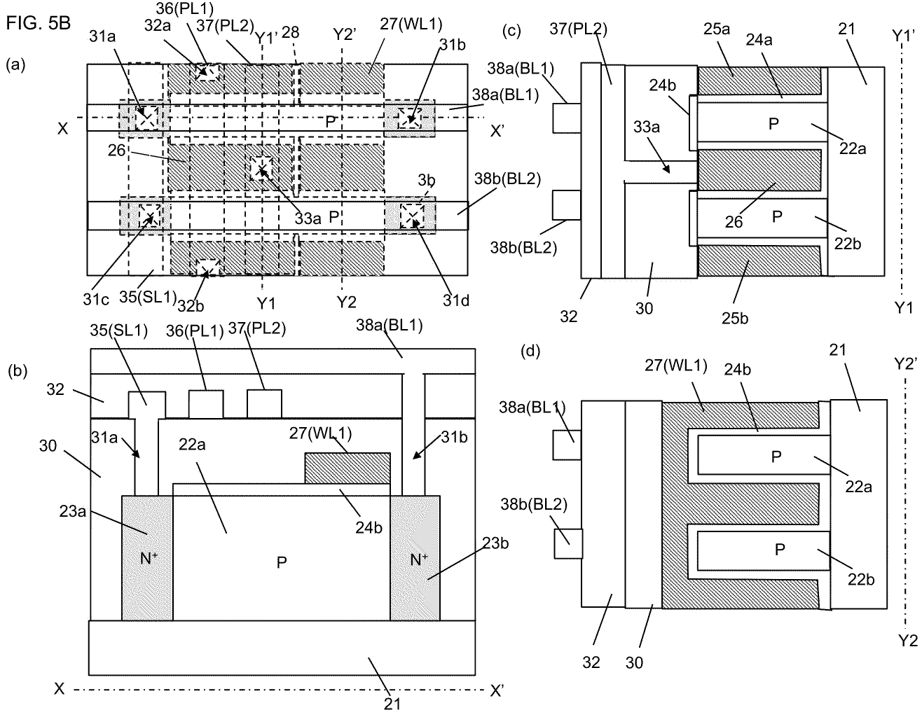

FIGS. 5A and 5B are structural diagrams for describing a dynamic flash memory according to a second embodiment. FIG. 5A illustrates a state in which the most basic structure of a plurality of dynamic flash memory cells is formed, and FIG. 5B illustrates a state in which a structure such as wirings is formed thereafter. FIGS. 5A(a) and 5B(a) are horizontal sectional views taken along line Z-Z’ in FIG. 5A(b) and 5B(b), respectively. FIG. 5A(b) and 5B(b) are vertical sectional views taken along line X-X’ in FIG. 5A(a) and 5B(a), respectively. FIG. 5A(c) and 5B(c) are vertical sectional views taken along line Y1-Y1‘ in FIGS. 5A(a) and 5B(a), respectively. FIG. 5A(d) and 5B(d) are vertical sectional views taken along line Y2-Y2’ in FIG. 5A(a) and 5b(a), respectively. In an actual dynamic flash memory device, many dynamic

As illustrated in FIG. 5A, a P layer 22a (an example of a “first semiconductor layer” in the claims) having a band shape and a P layer 22b (an example of a “second semiconductor layer” in the claims) having a band shape are parallel to each other on an insulating substrate 21 (an example of an “insulating substrate” in the claims) in plan view. An N⁺ layer 23a (an example of a “first impurity layer” in the claims) and an N⁺ layer 23b (an example of a “second impurity layer” in the claims) are connected to respective sides of the P layer 22a in an X-X’ direction. An N⁺ layer 23c (an example of a “third impurity layer” in the claims) and an N⁺ layer 23d (an example of a “fourth impurity layer” in the claims) are connected to respective sides of the P layer 22b in the X-X’ direction. A first gate insulating layer 24a (an example of a “first gate insulating layer” in the claims) is on both side surfaces of portions of the P layers 22a and 22b adjacent to the N⁺ layers 23a and 23c in a Y1-Y1’ direction, respectively. The first gate insulating layer 24a is continuous on the insulating substrate 21. Side surfaces of the first gate insulating layer 24a are covered with a first gate conductor layer 25a (an example of a “first gate conductor layer” in the claims), a fourth gate conductor layer 25b (an example of a “fourth gate conductor layer” in the claims), and a second gate conductor layer 26 (an example of a “second gate conductor layer” in the claims) that are isolated from one another. Portions of the P layers 22a and 22b adjacent to the N⁺ layers 23b and 23d, respectively, are covered with a second gate insulating layer 24b (an example of a “second gate insulating layer” in the claims) that is connected to the first gate insulating layer 24a. The second gate insulating layer 24b is covered with a third gate conductor layer 27 (an example of a “third gate conductor layer” in the claims) that is continuous and extends in a direction of the line Y2-Y2’. The second gate insulating layer 24b is continuous on the insulating substrate 21 and extends over an upper surface of the P layer 22a sandwiched by the first gate conductor layer 25a and the second gate conductor layer 26 and an upper surface of the P layer 22b sandwiched by the fourth gate conductor layer 25b and the second gate conductor layer 26 in plan view. The second gate insulating layer 24b is connected to a side surface of the first gate conductor layer 25a and a side surface of the fourth gate conductor layer 25b. Thus, the first gate conductor layer 25a, the fourth gate conductor layer 25b, the second gate conductor layer 26, and the third gate conductor layer 27 are insulated and isolated from one another. The second gate insulating layer 24b is covered with the third gate conductor layer 27 (an example of the “third gate conductor layer” in the claims) that is continuous and extends in the direction of the line Y2-Y2’.

As illustrated in FIG. 5B, a first interlayer insulating layer 30 covers the entirety. First contact holes 32a and 32b (an example of “first contact holes” in claims) are above the first gate conductor layer 25a and the fourth gate conductor layer 25b, respectively. A second contact hole 33a (an example of a “second contact hole” in claims) is above the second gate conductor layer 26. Third contact holes 31a and 31c (an example of “third contact holes” in claims) are above the N⁺ layers 23a and 23c, respectively. A fourth contact hole 31b (an example of a “fourth contact hole” in the claims) is above the N⁺ layer 23b. A fifth contact hole 31d (an example of a “fifth contact hole” in the claims) is above the N⁺ layer 23d. A first wiring conductor layer 36 (an example of a “first wiring conductor layer” in the claims) is connected to the first gate conductor layer 25a and the fourth gate conductor layer 25c via the first contact holes 32a and 32b, respectively. A second wiring conductor layer 37 (an example of a “second wiring conductor layer” in the claims) is connected to the second gate conductor layer 26 via the second contact hole 33a. A third wiring conductor layer 35 (an example of a “third wiring conductor layer” in the claims) is connected to the N⁺ layers 23a and 23c via the third contact holes 31a and 31c, respectively. A fourth wiring conductor layer 38a (an example of a “fourth wiring conductor layer” in the claims) is connected to the N⁺ layer 23b via the fourth contact hole 31b. A fifth wiring conductor layer 38b (an example of a “fifth wiring conductor layer” in the claims) is connected to the N⁺ layer 23d via the fifth contact hole 31d. The first wiring conductor layer 36, the second wiring conductor layer 37, and the third wiring conductor layer 35 extend in a direction of the line Y1-Y1’. The fourth wiring conductor layer 38a and the fifth wiring conductor layer 38b are perpendicular to the first wiring conductor layer 36, the second wiring conductor layer 37, and the third wiring conductor layer 35 and extend in a direction of the line X-X’.

As illustrated in FIG. 5B, the first wiring conductor layer 35 is connected to a first source line SL1. The second wiring conductor layer 36 is connected to a first plate line PL1. The third wiring conductor layer 37 is connected to a second plate line PL2. The third gate conductor layer 27 is connected to a first word line (WL1). The fourth wiring conductor layer 38a is connected to a first bit line BL1. The fifth wiring conductor layer 38b is connected to a second bit line BL2. In this manner, two dynamic flash memory cells are formed on the insulating substrate 21. In an actual dynamic flash memory device, many dynamic flash memory cells described above are arranged two dimensionally.

In the structure illustrated in FIG. 5B, connections to the second and third wiring conductor layers 36 and 37 via the contact holes 32a, 32b, and 33a are not used for the third gate conductor layer 27 connected to the first word line (WL1), unlike the first gate conductor layer 25a, the fourth gate conductor layer 25b, and the second gate conductor layer 26. Alternatively, a contact hole and a wiring conductor layer connected to the third gate conductor layer 27 via this contact hole may be provided above the third gate conductor layer 27.

A gate insulating layer (not illustrated) and a gate conductor layer (not illustrated) are deposited to cover the P layers 22a and 22b, and are then polished using a CMP (Chemical Mechanical Polishing) method such that upper surfaces of the gate insulating layer and the gate conductor layer are at positions of upper surfaces of the P layers 22a and 22b. Consequently, the first gate insulating layer 24a and the gate conductor layers 25a, 25b, and 26 that are isolated from each other on the respective side surfaces of the P layers 22a and 22b are formed. The first gate insulating layer 24a and the second gate insulating layer 24b, and the first gate conductor layer 25a, the fourth gate conductor layer 25b, the second gate conductor layer 26, and the third gate conductor layer 27 may be formed to have other structures by using other methods as long as the functions of the gate insulating layers and the gate conductor layers described above are obtained.

The present embodiment has features below.

### Feature 1

The second gate conductor layer 26 is also used as the gate conductor layer connected to the second plate line PL2 of the two dynamic flash memory cells formed at the P layer 22a and the P layer 22b. Thus, the degree of integration of the dynamic flash memory device can be increased.

### Feature 2

The first gate conductor layer 25a is used as a first gate conductor layer of a dynamic flash memory cell (not illustrated) located adjacently on the upper side of the P layer 22a in the drawing of FIG. 5A(a) and as the gate conductor layer. The first gate conductor layer 25b is used as a first gate conductor layer (not illustrated) of a dynamic flash memory cell (not illustrated) located adjacently on the lower side of the P layer 22b in the drawing of FIG. 5A(a) and as the gate conductor layer. Thus, the degree of integration of the dynamic flash memory device can be further increased.

### Feature 3

The N⁺ layers 23a and 23c can also be used as N⁺ layers connected to the first source line SL1 of dynamic flash memory cells (not illustrated) located adjacently in the direction of the line X-X’ in plan view. Thus, the degree of integration of the dynamic flash memory device can be further increased. Likewise, the N⁺ layers 23b and 23d can also be used as N⁺ layers respectively connected to the first bit line BL1 and the second bit line BL2 of dynamic flash memory cells (not illustrated) located adjacently in the direction of the line X-X’ in plan view. Thus, the degree of integration of the dynamic flash memory device can be further increased.

### Third Embodiment

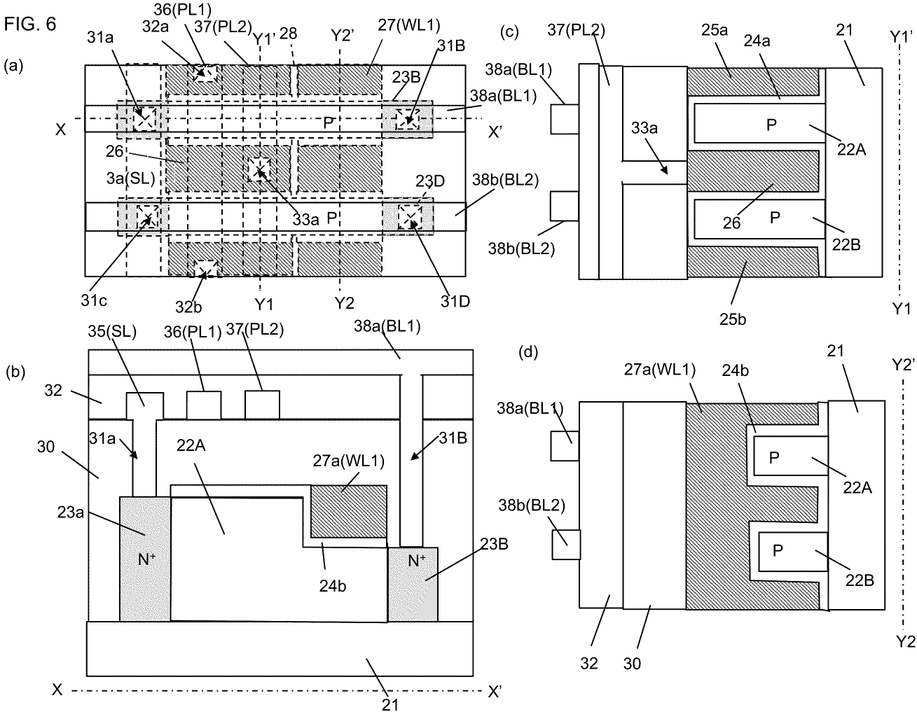

FIG. 6 is a structural diagram for describing a dynamic flash memory according to a third embodiment. FIG. 6(a) is a plan view of two dynamic flash memory cells. FIG. 6(b) is a vertical sectional view taken along line X-X’ in FIG. 6(a). FIG. 6(c) is a vertical sectional view taken along line Y1-Y1’ in FIG. 6(a). FIG. 6(d)is a vertical sectional view taken along line Y2-Y2’ in FIG. 6(a). In an actual dynamic flash memory device, many dynamic flash memory cells are arranged two dimensionally.

In the second embodiment, as illustrated in FIG. 5B, the height of the P layer 22a covered with the third gate conductor layer 27 is equal to the height of the portion of the P layer 22a sandwiched by the first gate conductor layer 25b, the fourth gate f conductor layer 25a, and the second gate conductor layer 26. By contrast, in the present embodiment, as illustrated in FIG. 6, the height of P layers 22A and 22B covered with a third gate conductor layer 27a is lower than the height of portions of the P layers 22A and 22B sandwiched by the first gate conductor layer 25a, the fourth gate f conductor layer 25b, and the second gate conductor layer 26. The P layers 22A and 22B are connected to N⁺ layers 23B and 23D, respectively. The N⁺ layers 23B and 23D are connected to the wiring conductor layers 38a and 38b via contact holes 31B and 31D, respectively. The rest is the same as the structure illustrated in FIG. 5B.

The present embodiment provides features below.

The height of portions of the P layers 22A and 22B covered with the third gate conductor layer 27a is set to be lower than the height of the portions of the P layers 22A and 22B sandwiched by the first and second gate conductor layers 25a, 25b, and 26, so that a third gate capacitance between the third gate conductor layer 27a and the P layers 22A and 22B can be made smaller than the third gate capacitance in FIG. 5. Thus, a ratio of the third gate capacitance to the first gate capacitance and a ratio of the third gate capacitance to the second gate capacitance can be reduced. This enables a fluctuation in the floating body voltage of the P layers 22A and 22B to be suppressed when the read pulse voltage is applied to the first word line WL1. As a result, the margin of the potential difference between the “1” potential and the “0” potential of the floating body is increased at the time of reading.

### Fourth Embodiment

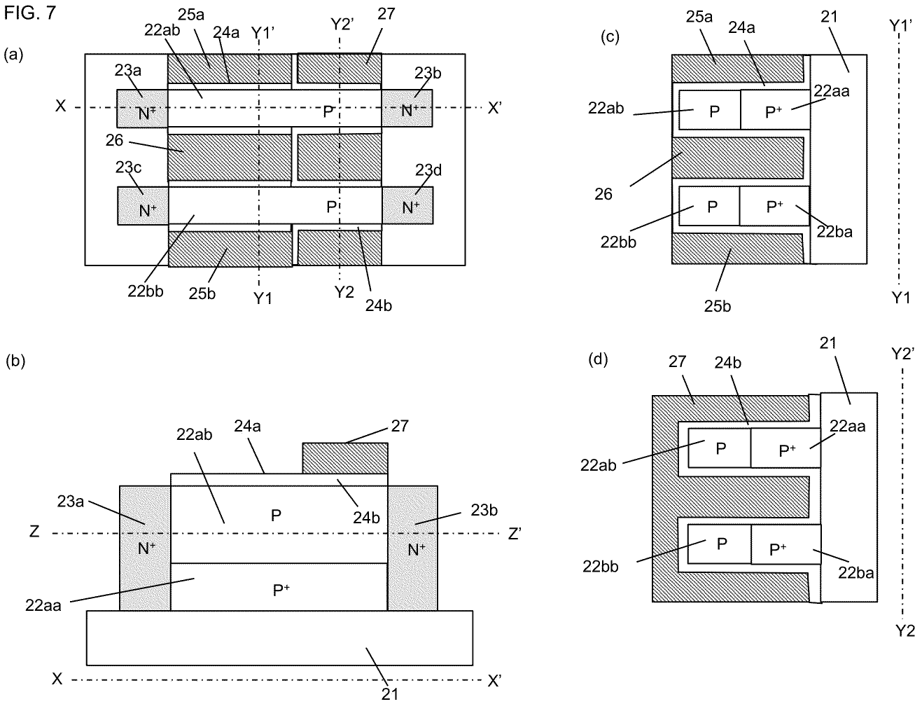

FIG. 7 is a structural diagram for describing a dynamic flash memory according to a fourth embodiment. FIG. 7(a) is a horizontal sectional view taken along line Z-Z’ in FIG. 7(b). FIG. 7(b) is a vertical sectional view taken along line X-X’ in FIG. 7(a). FIG. 7(c) is a vertical sectional view taken along line Y1-Y1’ in FIG. 7(a). FIG. 7(d) is a vertical sectional view taken along line Y2-Y2’ in FIG. 7(a). In an actual dynamic flash memory device, many dynamic flash memory cells are arranged two dimensionally. Since the structure such as wirings is substantially the same as that illustrated in FIG. 5B or the like, description will be omitted here.

In the second embodiment, the channel regions are formed of the P layers 22a and 22b as illustrated in FIG. 5B. By contrast, as illustrated in FIG. 7, a channel region sandwiched by the N⁺ layers 23a and 23b is formed of a P⁺ layer 22aa and a P layer 22ab formed on the insulating substrate 21 from the bottom. Likewise, a channel region sandwiched between the N⁺ layers 23c and 23d is formed of a P⁺ layer 22ba and a P layer 22bb formed on the insulating substrate 21 from the bottom. The rest is the same as the structure illustrated in FIG. 5A.

The present embodiment provides features below.

By providing the P⁺ layers 22aa and 22ba, a group of holes can be accumulated more in the channel regions than in the dynamic flash memory cells illustrated in FIG. 5B. Consequently, the dynamic flash memory cell with a wider operation margin is obtained.

### Other Embodiments

In FIG. 1, as the first to third gate conductor layers 5a, 5b, and 5c, a single conductor material layer or a plurality of conductor material layers including polycrystalline silicon containing a large amount of donor or acceptor impurity may be used in combination. Outer sides of the first to third gate conductor layers 5a, 5b, and 5c may be connected to wiring metal layers of W, for example. This also applies to the other embodiments.

In the first embodiment, the description is given that a dynamic flash memory with a wide operation margin can be obtained by making the first gate capacitance between the first gate conductor layer 5a and the P layer 2, the second gate capacitance between the second gate conductor layer 5b and the P layer 2, or the total capacitance of the first gate capacitance and the second gate capacitance larger than the third gate capacitance between the third gate conductor layer 5c and the P layer 2. This may be performed by a combination of gate lengths of the first to third gate conductor layers 5a, 5b, and 5c with film thicknesses or dielectric constants of the first and second gate insulating layers 4a and 4b such that one of the first and second gate capacitances of the first and second gate conductor layers 5a and 5b or the total capacitance of the first and second gate capacitances becomes larger than the third gate capacitance of the third gate conductor layer 5c. This also applies to the other embodiments.

The first dynamic flash memory cell illustrated in FIG. 1 may be vertically stacked in a plurality of stages to form a memory device. This also applies to the other embodiments. In this case, the third gate conductor layer 5c may be divided into two portions similarly to the first and second gate conductor layers 5a and 5b.

The sectional shape of the P layer 2 is rectangular in FIG. 1 but may be trapezoidal. The sectional shape of the portion of the P layer covered with the first gate insulating layer 4a may be different from the sectional shape of the portion of the P layer covered with the second gate insulating layer 4b. This also applies to the other embodiments.

In the description of the first embodiment, the source line SL is set to a negative bias during a data erase operation to draw the group of holes in the channel region 8 which is the floating body FB. Alternatively, instead of the source line SL, the bit line BL may be set to a negative bias or both the source line SL and the bit line BL may be set to negative biases to perform the data erase operation. Alternatively, the data erase operation may be performed under other voltage conditions.

The N⁺ layers 3a and 3b in FIG. 1 may be formed of a Si layer or another semiconductor material layer containing a donor impurity. The N⁺ layer 3a and the N⁺ layer 3b may be formed of different semiconductor material layers. This also applies to the other embodiments.

The insulating substrate 21 in FIG. 5 may have, for example, a well structure as long as the P layers 22a and 22b become electrically floating bodies.

Various embodiments and modifications can be made to the present invention without departing from the broad spirit and scope of the present invention. The embodiments described above are for describing an example of the present invention, and do not limit the scope of the present invention. The embodiments and modifications described above can be combined as desired. Even if some of the components of the above-described embodiment is omitted as necessary, such a configuration is also within the scope of the technical idea of the present invention.

### Industrial Applicability

According to the present invention, a memory device using a semiconductor element can implement a high-density and high-performance dynamic flash memory.

### [REFERENCE SIGNS LIST

1, 21 insulating substrate
2, 22a, 22b, 22A, 22B, 22ab, 22bb P layer
3a, 3b, 23a, 23b, 23c, 23d, 23B, 23D N⁺ layer
4a, 24a first gate insulating layer
4b, 24b second gate insulating layer
5a, 25a, 25b first gate conductor layer
5b, 26 second gate conductor layer
5c, 27 third gate conductor layer
6, 30, 32 insulating layer
11 group of holes
12a inversion layer
13 pinch-off point
SL1 first source line
PL1 first plate line
PL2 second plate line
WL1 first word line
BL1 first bit line
BL2 second bit line
31a, 31b, 31c, 31d, 32a, 32b, 33a contact hole
35 first wiring conductor layer
36 second wiring conductor layer
37 third wiring conductor layer
38a fourth wiring conductor layer
38b fifth wiring conductor layer
22aa, 22a P⁺ layer

1. A memory device using a semiconductor element, comprising:
a first semiconductor layer standing on a substrate in a direction perpendicular to the substrate, having a band shape, and serving as a floating body;
a first impurity layer and a second impurity layer connected to respective ends of the first semiconductor layer in a first direction parallel to the substrate;
a first gate insulating layer covering both side surfaces, of a portion of the first semiconductor layer adjacent to the first impurity layer, in a second direction perpendicular to the first direction in plan view;
a first gate conductor layer and a second gate conductor layer covering respective side surfaces of the first gate insulating layer and isolated from each other in plan view;
a second gate insulating layer covering a portion of the first semiconductor layer adjacent to the second impurity layer; and
a third gate conductor layer covering the second gate insulating layer, wherein
the first gate conductor layer, the second gate conductor layer, the third gate conductor layer, the first impurity layer, and the second impurity layer are configured to
perform a data write operation, a data read operation, and a data erase operation in accordance with control of voltages applied to the first gate conductor layer, the second gate conductor layer, the third gate conductor layer, the first impurity layer, and the second impurity layer.

2. The memory device using a semiconductor element according to claim 1, wherein
one of the first impurity layer and the second impurity layer is connected to a first source line and an other of the first impurity layer and the second impurity layer is connected to a first bit line,
the first gate conductor layer is connected to a first plate line,
the second gate conductor layer is connected to a second plate line,
the third gate conductor layer is connected to a first word line, and
in plan view, the first plate line, the second plate line, and the first word line extend in an identical direction that is the second direction and the first bit line extends in the first direction.

3. The memory device using a semiconductor element according to claim 1, wherein
in the direction perpendicular to the substrate, a height of a portion of the first semiconductor layer covered with the third gate conductor layer is lower than a height of a portion of the first semiconductor layer sandwiched by the first gate conductor layer and the second gate conductor layer.

4. The memory device using a semiconductor element according to claim 1, wherein
in the direction perpendicular to the substrate, the first semiconductor layer includes, in a lower portion of the first semiconductor layer, a semiconductor layer having an impurity concentration higher than an impurity concentration in an upper portion of the first semiconductor layer.

5. The memory device using a semiconductor element according to claim 1, wherein
in plan view, the third gate conductor layer includes two divisional conductor layers covering the second gate insulating layer on respective sides of the first semiconductor layer.

6. The memory device using a semiconductor element according to claim 1, wherein
the substrate is an insulating substrate.

7. The memory device using a semiconductor element according to claim 2, comprising:
a second semiconductor layer parallel to the first semiconductor layer on the substrate and having a band shape in plan view;
a third impurity layer and a fourth impurity layer connected to respective ends of the second semiconductor layer in the first direction;
the first gate insulating layer covering both side surfaces, of a portion of the second semiconductor layer adjacent to the third impurity layer, in the second direction;
the second gate conductor layer extending to the second semiconductor layer and covering one side surface of the first gate insulating layer covering the second semiconductor layer in plan view;
a fourth gate conductor layer covering a side surface, of the first gate insulating layer, opposite the second gate conductor layer in plan view;
a fourth gate insulating layer covering a portion of the second semiconductor layer adjacent to the fourth impurity layer;
the third gate conductor layer extending to cover the fourth gate insulating layer;
a first wiring conductor layer extending in the second direction and connecting the first gate conductor layer and the fourth gate conductor layer to each other via first contact holes located above the first gate conductor layer and the fourth gate conductor layer;
a second wiring conductor layer extending in the second direction and connected to the second gate conductor layer via a second contact hole located above the second gate conductor layer;
a third wiring conductor layer extending in the second direction and connected to the first impurity layer and the third impurity layer via third contact holes located above the first impurity layer and the third impurity layer;
a fourth wiring conductor layer extending in the first direction and connected to the second impurity layer via a fourth contact hole located above the second impurity layer; and
a fifth wiring conductor layer extending in the first direction and connected to the fourth impurity layer via a fifth contact hole located above the fourth impurity layer.

8. The memory device using a semiconductor element according to claim 6, comprising:
a sixth wiring conductor layer extending in the second direction and connected to the third gate conductor layer via a sixth contact hole located above the third gate conductor layer.

9. The memory device using a semiconductor element according to claim 1, wherein
a first gate capacitance between the first gate conductor layer and the first semiconductor layer, a second gate capacitance between the second gate conductor layer and the first semiconductor layer, or a total gate capacitance of the first gate capacitance and the second gate capacitance is larger than a third gate capacitance between the third gate conductor layer and the first semiconductor layer.

10. The memory device using a semiconductor element according to claim 1, wherein
the first gate conductor layer, the second gate conductor layer, the third gate conductor layer, the first impurity layer, and the second impurity layer are configured to perform the data write operation of holding a group of holes or a group of electrons that is a majority carrier in the first semiconductor layer and is generated by an impact ionization phenomenon or a gate-induced drain leakage current in the first semiconductor layer, in accordance with control of voltages applied to the first gate conductor layer, the second gate conductor layer, the third gate conductor layer, the first impurity layer, and the second impurity layer, and
the data erase operation of discharging the group of holes or the group of electrons that is the majority carrier in the first semiconductor layer from the first semiconductor layer, in accordance with control of voltages applied to the first gate conductor layer, the second gate conductor layer, the third gate conductor layer, the first impurity layer, and the second impurity layer.
